(19) United States
(12) Patent Application Publication
(10) Pub. No.: US 2024/0332151 A1
(43) Pub. Date: Oct. 3, 2024

(54) INTEGRATED PACKAGE AND METHOD FOR MAKING THE SAME

(71) Applicant: STATS ChipPAC Pte. Ltd., Singapore (SG)

(72) Inventors: JinHee JUNG, Incheon (KR); ChangOh KIM, Incheon (KR)

(21) Appl. No.: 18/605,841

(22) Filed: Mar. 15, 2024

(30) Foreign Application Priority Data
Mar. 29, 2023 (CN) 202310320858.5

(51) Int. Cl. H01L 23/498; H01L 21/32; H01L 21/48; H01L 23/00; H01L 23/552; H01L 25/065

(52) U.S. Cl. CPC H01L 23/49822; H01L 21/32; H01L 21/486; H01L 23/49816; H01L 23/552; H01L 24/05; H01L 24/29; H01L 25/0652; H01L 2224/05005; H01L 2224/05025; H01L 2224/29005; H01L 2224/29021; H01L 2924/0665; H01L 2924/15311; H01L 2924/18161; H01L 2924/182; H01L 2924/3025

(57) ABSTRACT

An integrated package and a method for making the same are provided. The integrated package may include: a substate; a first electronic component mounted on the substrate; a first dielectric layer formed on the substrate and covering the first electric component, wherein the dielectric layer is made of photo imageable dielectric material; a first redistribution layer formed in the first dielectric layer, wherein the first redistribution layer includes a first vertical portion running through the first dielectric layer and a first lateral portion formed on a top surface of the first dielectric layer; a second electronic component mounted above the first dielectric layer and coupled with the lateral portion of the first redistribution layer; and a second dielectric layer formed above the first dielectric layer and covering the second electronic component.

### TECHNICAL FIELD

The present application generally relates to semiconductor technology, and more particularly, to an integrated package and a method for making the same.

### BACKGROUND OF THE INVENTION

Package-on-Package (POP) is a type of packaging method that combines two or more integrated circuit (IC) packages together. In a typical POP, two or more packages are vertically connected (i.e., stacked) via solder balls that can direct signals between them. A POP assembly can more efficiently use space, and reduce lengths of signal tracks between the packages. Thus, a better electrical performance can be achieved, as the shorter track length may reduce noises and cross talks in integrated circuits and promote faster signal response. However, the process for forming the POP assembly is complex, and the yield is still low.

Therefore, a need exists for integrated packages with improved reliability.

### SUMMARY OF THE INVENTION

An objective of the present application is to provide an integrated package with high reliability.

According to an aspect of embodiments of the present application, an integrated package is provided. The integrated package may include: a substate; a first electronic component mounted on the substrate; a first dielectric layer formed on the substrate and covering the first electric component, wherein the dielectric layer is made of photo imageable dielectric material; a first redistribution layer formed in the first dielectric layer, wherein the first redistribution layer includes a first vertical portion running through the first dielectric layer and a first lateral portion formed on a top surface of the first dielectric layer; a second electronic component mounted above the first dielectric layer and coupled with the lateral portion of the first redistribution layer; and a second dielectric layer formed above the first dielectric layer and covering the second electronic component.

According to another aspect of embodiments of the present application, a method for making an integrated package is provided. The method may include: providing a package including: a substrate; and a first electronic component mounted on the substrate; forming a first dielectric layer on the substrate to cover the first electric component, wherein the dielectric layer is made of photo imageable dielectric material; performing photolithography and development processes on the first dielectric layer to form a first through hole in the first dielectric layer; forming a first redistribution layer in the first dielectric layer, wherein the first redistribution layer includes a first vertical portion formed in the first through hole and a first lateral portion formed on a top surface of the first dielectric layer; and mounting a second electronic component above the first dielectric layer, such that the second electronic component is coupled with the lateral portion of the first redistribution layer; and forming a second dielectric layer above the first dielectric layer to cover the second electric component.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view illustrating a PoP-type integrated package.

FIG. 2 is a cross-sectional view illustrating an integrated package according to an embodiment of the present application.

FIG. 3 is a cross-sectional view illustrating an integrated package according to another embodiment of the present application.

FIG. 4 is a cross-sectional view illustrating an integrated package according to another embodiment of the present application.

FIG. 5 is a cross-sectional view illustrating an integrated package according to another embodiment of the present application.

FIGS. 6A to 6G are cross-sectional views illustrating various steps of a method for making the integrated package illustrated in FIG. 2 according to an embodiment of the present application.

FIGS. 7A to 7C are cross-sectional views illustrating various steps of a method for making the integrated package illustrated in FIG. 3 according to an embodiment of the present application.

FIGS. 8A to 8D are cross-sectional views illustrating various steps of a method for making the integrated package illustrated in FIG. 4 according to an embodiment of the present application.

FIGS. 9A and 9B are cross-sectional views illustrating various steps of a method for making the integrated package illustrated in FIG. 5 according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

FIG. 1 illustrates a cross-sectional view of a PoP-type integrated package 100. The integrated package 100 may include a bottom package 110 and a top package 120. The bottom package 110 and the top package 120 may each include a substrate, contact pads formed on both sides of the substrate, one or more semiconductor devices mounted on the substrate, and an encapsulant covering the semiconductor devices. The top package 120 is mounted on the bottom package 110 via solder balls 130. In order to obtain good joint quality, contact pads within the substrate 122 of the top package 120 should be accurately aligned with respective contact pads within the substrate 112 of the bottom package 110. However, a warpage mismatch is often found between the top package 120 and the bottom package 110, resulting in defects such as opened or shorted solder joints as well as pad cratering effects at the interface of the substrate and the solder joint.

To address at least one of the above problems, an integrated package is provided in an aspect of the present application. The integrated package includes a substrate with a first electronic component mounted thereon. A first dielectric layer made of a photo imageable dielectric material is formed on the substrate to cover the first electronic component, and a redistribution layer (RDL) is formed in the first dielectric layer. The RDL can relocate contact pads within the substrate to desired locations on the first dielectric layer. Then, a second electronic component is mounted on the first dielectric layer and coupled with the RDL, and a second dielectric layer is formed on the first dielectric layer to cover the second electronic component.

Compared with the conventional PoP-type integrated package 100 shown in FIG. 1, the integrated package according to the embodiments of the present application does not include the substrate 122 of the top package 120 and the solder balls 130 in the POP-type integrated package 100. Accordingly, the integrated package according to the embodiments of the present application may have a reduced thickness, and does not have mismatch between the substrate and the solder balls. Moreover, the RDL can reroute connections to desired locations, rendering high flexibility in design. For example, the contact pads located in the center of the substrate can be redistributed to positions near an edge of the dielectric layer, for better access to the contact pads where necessary. With the aid of the RDL, two or more layers of packages can be stacked above the substrate.

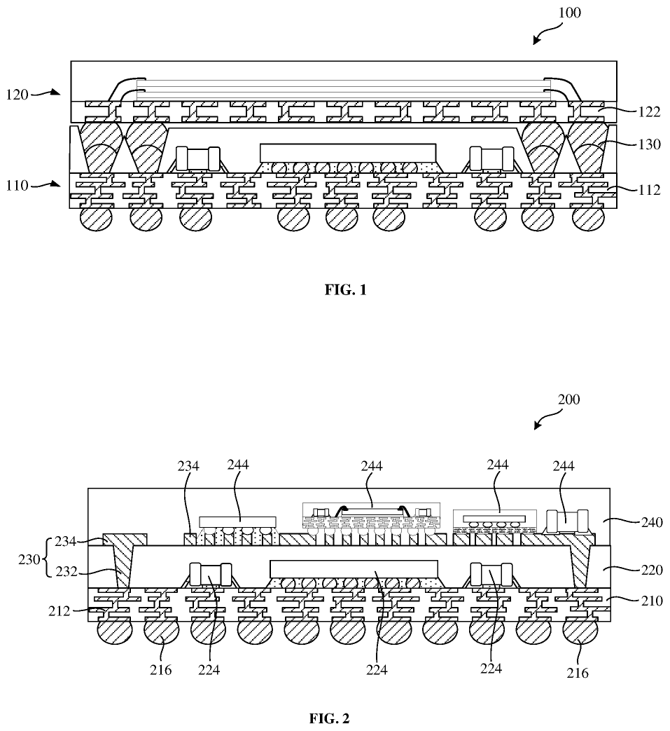

Referring to FIG. 2, a cross-sectional view of an integrated package 200 is illustrated according to an embodiment of the present disclosure.

As illustrated in FIG. 2, the integrated package 200 may include a substrate 210, one or more first electronic components 224 mounted on the substrate 210, a first dielectric layer 220 covering the first electric components 224, a redistribution layer (RDL) 230 formed in the first dielectric layer 220, one or more second electronic components 244 mounted above the first dielectric layer 220, and a second dielectric layer 240 covering the second electronic components 244.

The substrate 210 can provide support and connectivity for electrical components and devices. By way of example, the substrate 210 can include a printed circuit board (PCB), a carrier substrate, a semiconductor substrate with electrical interconnections, or a ceramic substrate. However, the substrate 210 is not to be limited to these examples. In other examples, the substrate 210 may include a laminate interposer, a strip interposer, a leadframe, or other suitable substrates. The substrate 210 may include any structure on or in which an integrated circuit system can be fabricated. For example, the substrate 210 may include one or more insulating or passivation layers, one or more conductive vias formed through the insulating layers, and one or more conductive layers formed over or between the insulating layers.

In some embodiments, the substrate 210 may include a plurality of interconnection structures 212. The interconnection structures 212 can provide connectivity for electrical components mounted on the substrate 210. The interconnection structures 212 may include one or more of Cu, Al, Sn, Ni, Au, Ag, or any other suitable electrically conductive materials. In some examples, the interconnection structures 212 may include redistribution structures. The redistribution structures may include one or more dielectric layers and one or more conductive layers between and through the dielectric layers. The conductive layers may define pads, traces and plugs through which electrical signals or voltages can be distributed horizontally and vertically across the redistribution structures.

The interconnection structures 212 can provide contact pads along the top surface and the bottom surface of the substrate 210 for mounting devices, chips, and interconnects thereon. For example, as shown in FIG. 2, a plurality of solder bumps or solder balls 216 are formed on the contact pads along the bottom surface of the substrate 210. The solder balls 216 are used to interface with or attach the integrated package 200 to an external device, such as to an external substrate.

Further, as shown in FIG. 2, a plurality of first electronic components 224 are mounted on the contact pads along the top surface of the substrate 210. The first electronic components 224 may include any of a variety of types of semiconductor dice, semiconductor packages, or discrete devices. For example, the first electronic components 224 may include a digital signal processor (DSP), a microcontroller, a microprocessor, a network processor, a power management processor, an audio processor, a video processor, an RF circuit, a wireless baseband system-on-chip (SoC) processor, a sensor, a memory controller, a memory device, an application specific integrated circuit, etc. The first electronic components 224 may also include one or more passive electrical components such as resistors, capacitors, inductors, etc. The first electronic components 224 can be mounted on the contact pads in a flip-chip configuration, or by wire bonding or any other suitable surface mounting techniques. In some embodiments, an underfill material is formed between the first electronic components 224 and the substrate 210 and optionally on side walls of the first electronic components 224. The underfill material may include a polymer composite material, such as epoxy resin, epoxy acrylate, or polymer with or without a filler, and may provide mechanical support to the first electronic components 224, helping to mitigate the risk of crack or delamination due to differential thermal expansion between the first electronic components 224 and the substrate 210.

The first dielectric layer 220 is formed on the substrate 210 and covers the first electric components 224. The first dielectric layer 220 is made of a photo imageable dielectric (PID) material. The PID material may include a photo initiator (photo sensitive agent) that may be cured by UV light. In some embodiments, the PID material may include photosensitive polyimide, polybenzoxazole (PBO), phenolic polymers, or benzocyclobutene polymers. The PID material may be coated on a substrate and may then be exposed to a lithographic source via a photomask, wherein the photomask defines cavities to be produced. A portion of the PID material may be developed and an exposed portion or an unexposed portion (depending on whether the PID material is positive or negative) may be removed to obtain a plurality of cavities. Examples of photolithography processes may include X-ray lithography, UV lithography, stereo lithography, e-beam lithography and laser lithography.

The first dielectric layer 220 not only protects the first electric components 224 from external elements and contaminants, but also facilitates the formation of the RDL 230. As shown in FIG. 2, a plurality of through holes are formed in the first dielectric layer 220 to expose the contact pads of the interconnection structures 212, and a conductive material is filled into the through holes to form a vertical portion 232 of the RDL 230. Thus, the vertical portion 232 of the RDL 230 electrically contacts the contact pads of the interconnection structures 212 along the top surface of the substrate 210. The RDL 230 may further include a lateral portion 234 on the top surface of the first dielectric layer 220. The lateral portion 234 of the RDL 230 may define pads for mounting devices, chips, and interconnects, and also define traces through which electrical signals or voltages can be distributed. Thus, the RDL 230 can provide connectivity for electrical components mounted thereon. The RDL 230 (including the vertical portion 232 and the lateral portion 234) may include one or more of Cu, Al, Sn, Ni, Au, Ag, or any other suitable electrically conductive materials.

Continuing referring to FIG. 2, a plurality of second electronic components 244 are mounted on the lateral portion (e.g., contact pads) 234 of the RDL 230. Similar as the first electronic components 224 described above, the second electronic components 244 may also include any of a variety of types of semiconductor dice, semiconductor packages, or discrete devices, and will not be elaborated herein. As shown in FIG. 2, the second electronic components 244 are directedly mounted on the lateral portion 234 of the RDL 230, and the RDL 230 can provide connectivity between the second electronic components 244 and the first electric components 224. Accordingly, the integrated package 200 may have a reduced thickness, and does not have the warpage mismatch as shown in FIG. 1. Further, the RDL 230 can reroute the contact pads on the substrate 210 to desired locations on the top surface of the first dielectric layer 220, and thus the second electronic components 244 can be disposed at any positions as desired.

The second dielectric layer 240 is formed on the first dielectric layer 220 and covers the second electronic components 244. In some embodiments, the second dielectric layer 240 may be a molding compound that covers the second electronic component 244 and the lateral portion 234 of the RDL 230. The second dielectric layer 240 can provide mechanical protection, environmental protection, and a hermetic seal for the integrated package 200. For example, the second dielectric layer 240 can be made from an epoxy molding compound (EMC), film assisted molding, or polymide compound, for example.

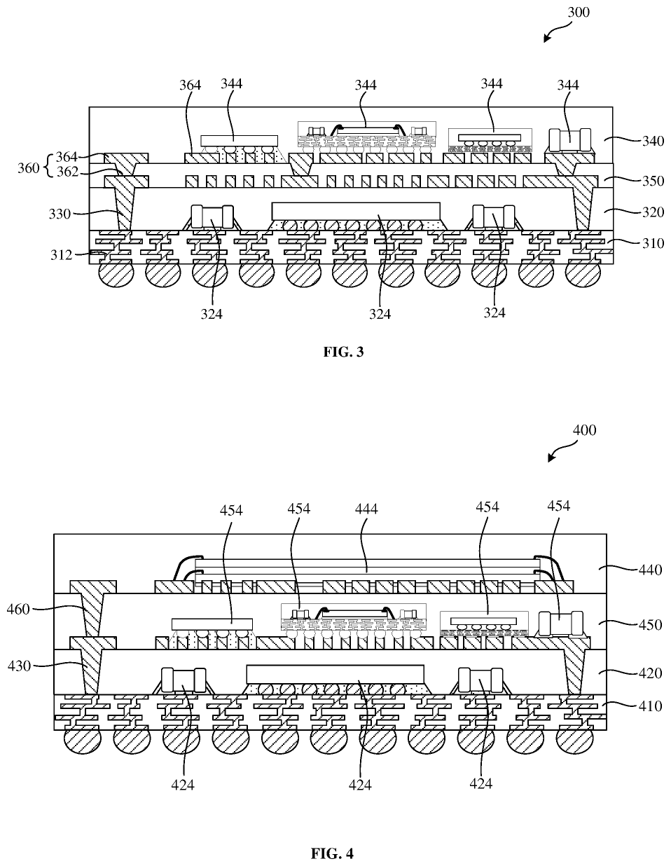

Referring now to FIG. 3, an integrated package 300 is illustrated according to another embodiment of the present application. The integrated package 300 includes a substrate 310, one or more first electronic components 324 mounted on the substrate 310, a first dielectric layer 320 covering the first electric components 324, a first RDL 330 formed in the first dielectric layer 320, a third dielectric layer 350 formed on the first dielectric layer 320, a second RDL 360 formed in the third dielectric layer 350, one or more second electronic components 344 mounted on the third dielectric layer 350, and a second dielectric layer 340 covering the second electronic components 344.

The integrated package 300 of FIG. 3 is different from the integrated package 200 of FIG. 2 in that the integrated package 300 of FIG. 3 further includes the third dielectric layer 350 and the second RDL 360.

Specifically, the third dielectric layer 350 is formed on the first dielectric layer 320 and covers the lateral portion of the first RDL 360. The third dielectric layer 350 can be made of PID material similar as the first dielectric layer 320, such as photosensitive polyimide, polybenzoxazole (PBO), phenolic polymers, or benzocyclobutene (BCB) polymers. However, the present application is not limited thereto, and the third dielectric layer 350 can be made of other dielectric material such as a molding compound.

As shown in FIG. 3, a plurality of through holes are formed in the third dielectric layer 350 to expose the lateral portion of the first RDL 330, and a conductive material is filled into the through holes to form a vertical portion 362 of the second RDL 360. Thus, the vertical portion 362 of the second RDL 360 can be electrically coupled to the contact pads of the interconnection structures 312 and the first electronic components 324 through the first RDL 330. The second RDL 360 further includes a lateral portion 364 on the top surface of the third dielectric layer 350. The lateral portion 364 of the second RDL 360 can define pads for mounting devices, chips, and interconnects, and also define traces through which electrical signals or voltages can be distributed. Accordingly, the second electronic components 344 mounted on the lateral portion 364 of the second RDL 360 can be coupled to the first electronic components 324 and other components in the integrated package 300 through the first RDL 330 and the second RDL 360. Compared with the integrated package 200 shown in FIG. 2, the two RDLs 330 and 360 can provide more design flexibility for the integrated package 300.

Referring now to FIG. 4, an integrated package 400 is illustrated according to another embodiment of the present application. The integrated package 400 includes a substrate 410, one or more first electronic components 424 mounted on the substrate 410, a first dielectric layer 420 covering the first electric components 424, a first RDL 430 formed in the first dielectric layer 420, one or more third electronic components 454 mounted on the lateral portion of the first RDL 430, a third dielectric layer 450 formed on the first dielectric layer 420 and covering the third electronic components 454, a second RDL 460 formed in the third dielectric layer 450, one or more second electronic components 444 mounted on the third dielectric layer 450, and a second dielectric layer 440 covering the second electronic components 444.

The integrated package 400 of FIG. 4 is different from the integrated package 300 of FIG. 3 in that the integrated package 400 of FIG. 4 further includes the third electronic components 454. Specifically, the third electronic components 454 may include any of a variety of types of semiconductor dice, semiconductor packages, or discrete devices, and can be mounted on the lateral portion of the first RDL 430 in a flip-chip configuration, or by wire bonding or any other suitable surface mounting techniques. Thus, the integrated package 400 of FIG. 4 may have a higher integration density.

However, the present application is not limited to the embodiments shown in FIGS. 3 and 4. In other embodiments, the integrated package of the present application may include more than two RDLs and more electronic components formed on the RDLs, so as to further increase the integration density.

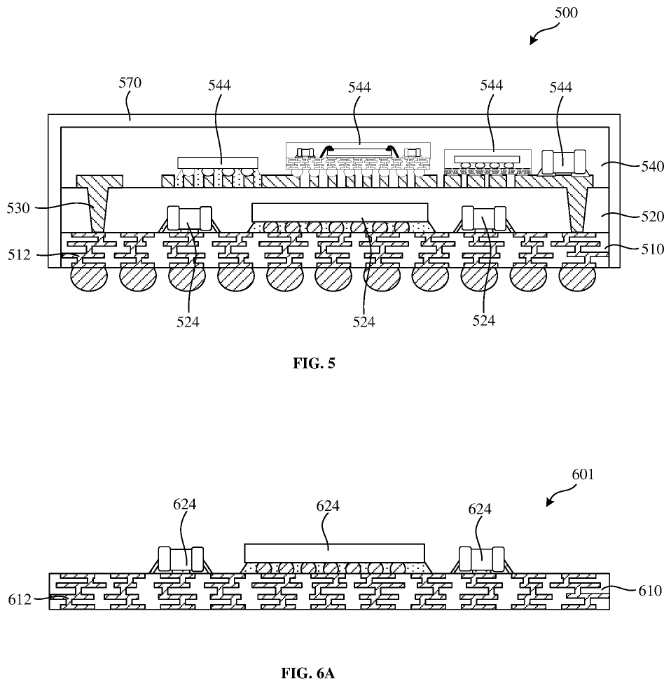

Referring now to FIG. 5, an integrated package 500 is illustrated according to another embodiment of the present application. The integrated package 500 includes a substrate 510, one or more first electronic components 524 mounted on the substrate 510, a first dielectric layer 520 covering the first electric components 524, a RDL 530 formed in the first dielectric layer 520, one or more second electronic components 544 mounted on a lateral portion of the RDL 530, a second dielectric layer 540 covering the second electronic components 544, and an electromagnetic interference (EMI) shielding layer 570 at least covering the second dielectric layer 540.

The integrated package 500 of FIG. 5 is different from the integrated package 200 of FIG. 2 in that the integrated package 500 of FIG. 5 further includes the EMI shielding layer 570. Specifically, as shown in FIG. 5, the EMI shielding layer 570 may be a conformal shield that follows the shapes and/or contours of the second dielectric layer 540, the first dielectric layer 520 and the substrate 510. That is, the EMI shielding layer 570 may cover the top and lateral surfaces of the second dielectric layer 540, the lateral surface of the first dielectric layer 520, and the lateral surface of the substrate 510. However, the bottom surface of the substrate 510 and the solder balls formed thereon are exposed from the EMI shielding layer 570. In some embodiments, the EMI shielding layer 570 may be made of copper, aluminum, iron, or any other suitable material for EMI shielding. The EMI shielding layer 570 can shield EMI or other interferences induced to (or generated by) the electronic components within the integrated package 500.

While the integrated package of the present application is described in conjunction with corresponding figures, it will be understood by those skilled in the art that modifications and adaptations to the integrated package may be made without departing from the scope of the present invention. For example, the EMI shielding layer may be further formed on the integrated package shown in FIG. 3 and the integrated package 400 shown in FIG. 4.

According to another aspect of the present application, a method for making an integrated package is provided.

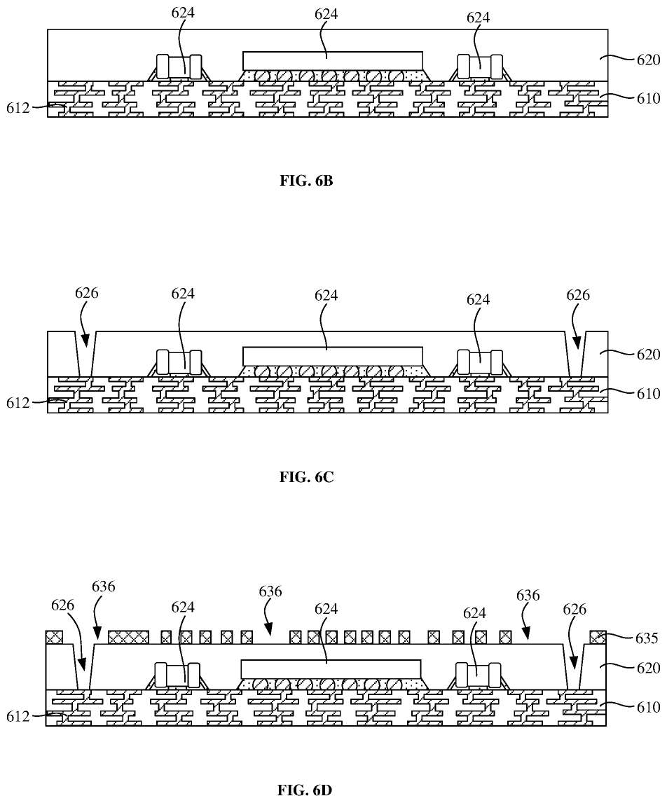

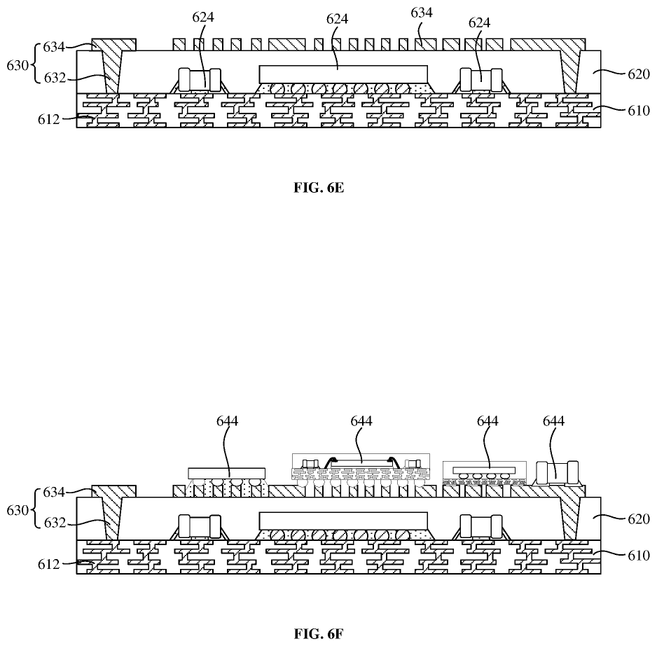

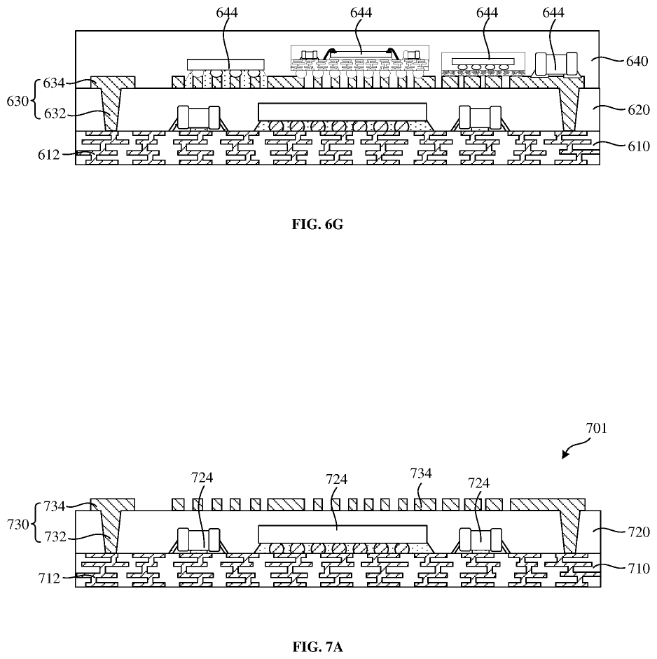

Referring to FIGS. 6A-6G, cross-sectional views illustrating a method for making an integrated package are shown according to an embodiment of the present application. For example, the method may be used to make the integrated package 200 shown in FIG. 2.

As shown in FIG. 6A, a package 601 is provided. The package 601 may include a substrate 610 and a plurality of first electronic components 624 mounted thereon. The substrate 610 may include a plurality of interconnection structures 612. The interconnection structures 612 can provide connectivity for electrical components mounted on the substrate 610.

The interconnection structures 612 can provide contact pads along the top surface and the bottom surface of the substrate 610 for mounting devices, chips, and interconnects. For example, the first electronic components 624 are mounted on the contact pads along the top surface of the substrate 610. The first electronic components 624 may include any of a variety of types of semiconductor dice, semiconductor packages, or discrete devices. In some embodiments, an underfill material is formed between the first electronic components 624 and the substrate 610 and optionally on side walls of the first electronic components 624. The underfill material may provide mechanical support to the first electronic components 624, helping to mitigate the risk of crack or delamination due to differential thermal expansion between the first electronic components 624 and the substrate 610.

In some embodiments, a plurality of solder bumps or solder balls (not shown) may be formed on the contact pads along the bottom surface of the substrate 610. The solder balls 616 are used to interface with or attach the integrated package to an external device, such as to an external substrate. In some embodiments, the solder bumps or solder balls may be formed in subsequent steps.

Referring to FIG. 6B, a first dielectric layer 620 is formed on the substrate 610 to cover the first electric components 624.

The first dielectric layer 620 is made of a photo imageable dielectric (PID) material. The PID material may include a photo initiator (photo sensitive agent) that may be cured by UV light. In some embodiments, the PID material may include photosensitive polyimide, polybenzoxazole (PBO), phenolic polymers, or benzocyclobutene polymers. In some embodiments, the PID material may act as a positive photoresist, in which the PID material can be degraded by light and the developer may dissolve away the regions that were exposed to light, leaving behind a coating where a mask was placed. In some embodiments, the PID material may act as a negative photoresist, in which the PID material can be strengthened (either polymerized or cross-linked) by light, and the developer may dissolve away only the regions that were not exposed to light, leaving behind a coating in areas where the mask was not placed.

In some embodiments, the first dielectric layer 620 may be formed on the substrate 610 using a coating process, such as spin coating or slit coating, but the present application is not limited thereto.

Referring to FIG. 6C, photolithography and development processes are performed on the first dielectric layer 620 to form one or more first through holes 626 in the first dielectric layer 620.

In some embodiments where the first dielectric layer 620 is a positive photoresist, the first dielectric layer 620 is first covered by a photomask which has openings corresponding to the first through holes 626 to be formed. Then, the first dielectric layer 620 is exposed to ultraviolet light or other electromagnetic radiation with use of the photomask. Afterwards, the first dielectric layer 620 is developed, to remove the portions of the first dielectric layer 620 that are exposed to a sufficient amount of light during exposure to form the first through holes 626. In some other embodiments, the first dielectric layer 620 may act as a negative photoresist, and the first through holes 626 can be formed using similar photolithography and development processes as described above except that the portions of the first dielectric layer 620 exposed to light are different. In some embodiments, the photomask can be omitted, and a laser direct imaging process or other similar processes can be applied to cure some portions of the first dielectric layer 620. Then, then first dielectric layer 620 may be developed to form the first through holes 626.

In the example shown in FIG. 6C, each of the first through holes 626 may have a sloping lateral surface, such that a conductive material can be easily accommodated into the first through holes 626. However, the present application is not limited thereto, and in other examples, the lateral surfaces of the first through holes 626 may be extending in a vertical direction.

Afterwards, referring to FIG. 6D, a dry film 635 is laminated on the first dielectric layer 620, and then a plurality of openings 636 are formed in the dry film 635. The plurality of openings 636 may expose the first through holes 626 and are formed at locations where a lateral portion of a first RDL are to be formed in a subsequent step.

In some embodiments, the dry film 635 may include a polymer which is sensitive to ultraviolet light, and can be adhered to the first dielectric layer 620 upon heating. For example, a hot roller or hot laminator can be used to adhere the dry film 635 onto the he first dielectric layer 620. The dry film 635 can form different patterns using a photolithography method, which will not be elaborated herein. Once photosensitized, the dry film 635 can be developed using an alkaline solution or other suitable developing solutions to form the openings 636.

Afterwards, referring to both FIGS. 6D and 6E, a first RDL 630 is formed in the first dielectric layer 620. The first RDL 630 may include a first vertical portion 632 and a first lateral portion 634. The first vertical portion 632 may fill the first through holes 626 formed in the first dielectric layer 620 and electrically contact the interconnection structures 612, and the first lateral portion 634 may fill the openings 636 formed in the dry film 635.

In some embodiments, an electroless-plating process may be performed to deposit a conductive material on the first dielectric layer 620 and the dry film 635, such that the conductive material may fill the first through hole 626 in the first dielectric layer 620 and the openings 636 in the dry film 635, and cover a top surface of the dry film 635. In some embodiments, the conductive material can be formed using spray coating, sputtering, or any other suitable metal deposition process. The conductive material may include one or more of Cu, Al, Sn, Ni, Au, Ag, or any other suitable materials. After the conductive material has accumulated to a sufficient thickness, the electroless-plating process stops, and the dry film 635 and the conductive material formed thereon are stripped away from the first dielectric layer 620, such that the conductive material left in the first through hole 626 of the first dielectric layer 620 forms the first vertical portion 632 of the first RDL 630 and the conductive material left on the top surface of the first dielectric layer 620 forms the first lateral portion 634 of the first RDL 630. The lateral portion 634 of the first RDL 630 may define pads for mounting devices, chips, and interconnects, and also define traces through which electrical signals or voltages can be distributed.

Afterwards, referring to FIG. 6F, a plurality of second electronic component 644 are mounted on the first lateral portion 634 of the first RDL 630.

The second electronic components 644 may include any of a variety of types of semiconductor dice, semiconductor packages, or discrete devices. Depending on their structures and configurations, the second electronic components 644 may be mounted on the first lateral portion 634 of the first RDL 630 in a flip-chip configuration, or by wire bonding or any other suitable surface mounting techniques. In some embodiments, an underfill material may be formed between the second electronic components 644 and the first dielectric layer 620 and optionally on side walls of the second electronic components 644.

At last, referring to FIG. 6G, a second dielectric layer 640 is formed on the first dielectric layer 620 to cover the second electric components 644.

In some embodiments, the second dielectric layer 640 may be formed on the first dielectric layer 620 using a paste printing, compressive molding, transfer molding, liquid encapsulant molding, vacuum lamination, spin coating, or other suitable process.

In some embodiments, the second dielectric layer 640 may include a molding compound. For example, the second dielectric layer 640 may be made of a polymer composite material, such as epoxy resin with filler, epoxy acrylate with filler, or polymer with proper filler, but the scope of this application is not limited thereto. The second dielectric layer 640 can provide structural support for the integrated package, and environmentally protect the second electric components 644 and other components in the integrated package from external elements and contaminants.

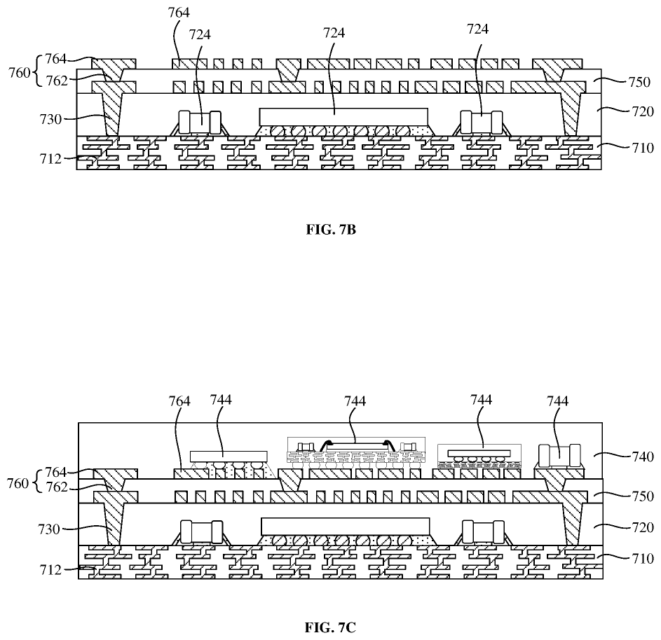

Referring to FIGS. 7A-7C, cross-sectional views illustrating a method for making an integrated package are shown according to another embodiment of the present application. For example, the method may be used to make the integrated package 300 shown in FIG. 3.

As shown in FIG. 7A, a package 701 is provided. The package 701 may include a substrate 710, one or more first electronic components 724 mounted on the substrate 710, a first dielectric layer 720 covering the first electric components 724, and a first RDL 730 formed in the first dielectric layer 720. The first RDL 730 includes a first vertical portion 732 running through the first dielectric layer 720 and a first lateral portion 734 formed on a top surface of the first dielectric layer 720. The package 701 is similar to the structure shown in FIG. 6E, and will not be elaborated herein.

Referring to FIG. 7B, a third dielectric layer 750 is formed on the first dielectric layer 720, and a second RDL 760 is formed in the third dielectric layer 750. The second RDL 760 may include a second vertical portion 762 running through the third dielectric layer 750 and coupled with the first lateral portion of the first RDL 730, and a second lateral portion 764 formed on the top surface of the third dielectric layer 750. The second lateral portion 764 of the second RDL 760 may define pads for mounting devices, chips, and interconnects, and also define traces through which electrical signals or voltages can be distributed.

In some embodiments, the third dielectric layer 750 is made of a photo imageable dielectric (PID) material. The PID material may include a photo initiator (photo sensitive agent) that may be cured by UV light. In some embodiments, the third dielectric layer 750 may be formed on the first dielectric layer 720 by a coating process. Then, photolithography and development processes may be performed on the third dielectric layer 750 to form one or more second through holes (not shown) therein. The second through holes may expose the first lateral portion of the first RDL 730. Afterwards, the third dielectric layer 750 is covered by a patterned dry film, and an electroless-plating process is performed to deposit a conductive material on the third dielectric layer 750, such that the conductive material fills the second through holes in the third dielectric layer 750 to form the second vertical portion 762 of the second RDL 760. After the patterned dry film is stripped from the third dielectric layer 750, the conductive material left on the top surface of the third dielectric layer 750 forms the second lateral portion 764 of the second RDL 760.

Afterwards, referring to FIG. 7C, a plurality of second electronic components 744 are mounted on the second lateral portion 764 of the second RDL 760, and a second dielectric layer 740 is formed on the third dielectric layer 750 to cover the second electric components 744.

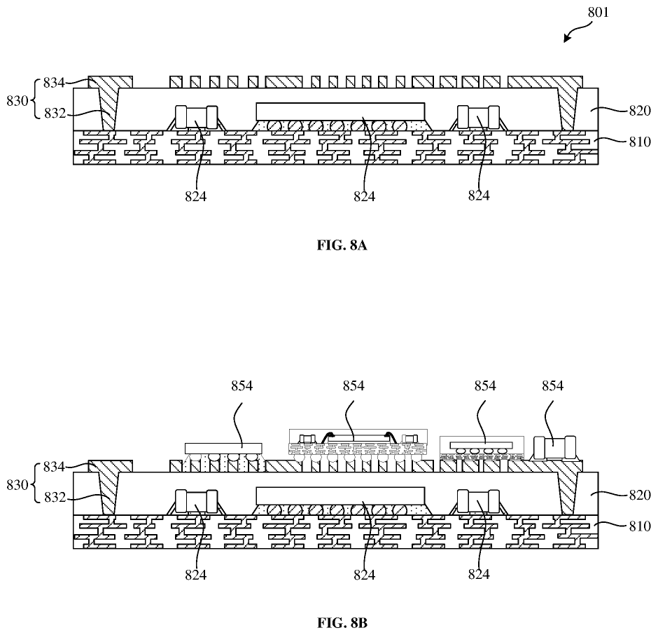

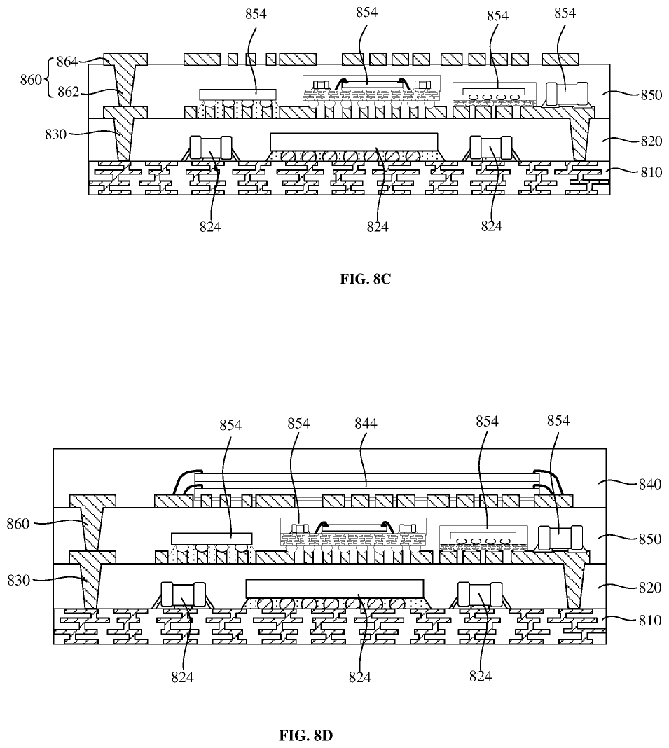

Referring to FIGS. 8A-8D, cross-sectional views illustrating a method for making an integrated package are shown according to another embodiment of the present application. For example, the method may be used to make the integrated package 400 shown in FIG. 4.

As shown in FIG. 8A, a package 801 is provided. The package 801 may include a substrate 810, one or more first electronic components 824 mounted on the substrate 810, a first dielectric layer 820 covering the first electric components 824, and a first RDL 830 formed in the first dielectric layer 820. The first RDL 830 includes a first vertical portion 832 running through the first dielectric layer 820 and a first lateral portion 834 formed on a top surface of the first dielectric layer 820. The package 801 is similar to the package structure shown in FIG. 6E, and will not be elaborated herein.

Referring to FIG. 8B, one or more third electronic components 854 are mounted on the lateral portion 834 of the first redistribution layer 830. The third electronic components 854 may include any of a variety of types of semiconductor dice, semiconductor packages, or discrete devices. Depending on their structures and configurations, the third electronic components 854 may be mounted on the first lateral portion 834 of the first RDL 830 in a flip-chip configuration, or by wire bonding or any other suitable surface mounting techniques. In some embodiments, an underfill material may be formed between the third electronic components 854 and the first dielectric layer 820 and optionally on side walls of the third electronic components 854.

Referring to FIG. 8C, a third dielectric layer 850 is formed on the first dielectric layer 820, and a second RDL 860 is formed in the third dielectric layer 850. The second RDL 860 may include a second vertical portion 862 running through the third dielectric layer 850 and coupled with the first lateral portion of the first RDL 830, and a second lateral portion 864 formed on the top surface of the third dielectric layer 850. The second lateral portion 864 of the second RDL 860 may define pads for mounting devices, chips, and interconnects, and also define traces through which electrical signals or voltages can be distributed.

Afterwards, referring to FIG. 8D, a second electronic component 844 is mounted on the second lateral portion 864 of the second RDL 860, and a second dielectric layer 840 is formed on the third dielectric layer 850 to cover the second electric component 844.

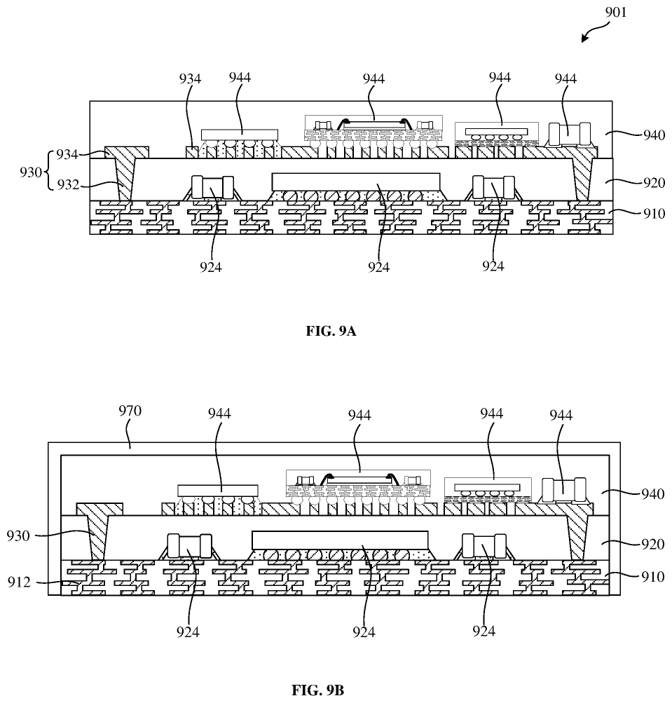

Referring to FIGS. 9A-9B, cross-sectional views illustrating a method for making an integrated package are shown according to another embodiment of the present application. For example, the method may be used to make the integrated package 500 shown in FIG. 5.

As shown in FIG. 9A, a package 901 is provided. The package 901 may include a substrate 910, one or more first electronic components 924 mounted on the substrate 910, a first dielectric layer 920 covering the first electric components 924, a RDL 930 formed in the first dielectric layer 920, one or more second electronic components 944 mounted on the RDL 930, and a second dielectric layer 940 covering the second electronic components 944. The RDL 930 includes a vertical portion 932 running through the first dielectric layer 920 and a lateral portion 934 formed on a top surface of the first dielectric layer 920. The package 901 is similar to the structure shown in FIG. 6G, and will not be elaborated herein.

Afterwards, as shown in FIG. 9B, an electromagnetic interference (EMI) shielding layer 970 is formed over the second dielectric layer 940.

In some embodiments, the EMI shielding layer 970 may be made of copper, aluminum, iron, or any other suitable material for EMI shielding. In some embodiments, the EMI shielding layer 970 may be formed by spray coating, plating, sputtering, or any other suitable metal deposition process. The EMI shielding layer 970 may be a conformal shield that follows the shapes and/or contours of the second dielectric layer 940, the first dielectric layer 920 and the substrate 910. The EMI shielding layer 970 can shield EMI or other interferences induced to (or generated by) the electronic components within integrated package.

While different processes for making the integrated package are illustrated in conjunction with FIGS. 6A-6G, FIGS. 7A-7C, FIGS. 8A-8D and FIGS. 9A-9B, it will be appreciated by those skilled in the art that modifications and adaptations to the processes may be made without departing from the scope of the present invention.

The discussion herein included numerous illustrative figures that showed various portions of an electronic package assembly and method of manufacturing thereof. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An integrated package, comprising:
a substate;
a first electronic component mounted on the substrate;
a first dielectric layer formed on the substrate and covering the first electric component, wherein the first dielectric layer is made of photo imageable dielectric material;
a first redistribution layer formed in the first dielectric layer, wherein the first redistribution layer comprises a first vertical portion running through the first dielectric layer and a first lateral portion formed on a top surface of the first dielectric layer;
a second electronic component mounted above the first dielectric layer and coupled with the lateral portion of the first redistribution layer; and
a second dielectric layer formed above the first dielectric layer and covering the second electronic component.

2. The integrated package of claim 1, wherein the photo imageable dielectric material comprises one or more of photosensitive polyimide, polybenzoxazole (PBO), phenolic polymers, and benzocyclobutene polymers.

3. The integrated package of claim 1, wherein the second dielectric layer comprises molding compound.

4. The integrated package of claim 1, further comprising:
a third dielectric layer formed between the first dielectric layer and the second dielectric layer; and
a second redistribution layer formed in the third dielectric layer, wherein the second redistribution layer comprises a second vertical portion running through the third dielectric layer and coupled with the first lateral portion of the first redistribution layer, and a second lateral portion formed on a top surface of the third dielectric layer and coupled with the second electronic component.

5. The integrated package of claim 4, wherein the third dielectric layer is made of photo imageable dielectric material.

6. The integrated package of claim 4, further comprising:
a third electronic component mounted above the first dielectric layer, wherein the third electronic component is coupled with the lateral portion of the first redistribution layer and is covered by the third dielectric layer.

7. The integrated package of claim 1, further comprising:
an electromagnetic interference (EMI) shielding layer at least covering the second dielectric layer.

8. A method for making an integrated package, comprising:
providing a package comprising:
a substrate; and
a first electronic component mounted on the substrate;
forming a first dielectric layer on the substrate to cover the first electric component, wherein the first dielectric layer is made of photo imageable dielectric material;
performing photolithography and development processes on the first dielectric layer to form a first through hole in the first dielectric layer;
forming a first redistribution layer in the first dielectric layer, wherein the first redistribution layer comprises a first vertical portion formed in the first through hole and a first lateral portion formed on a top surface of the first dielectric layer; and
mounting a second electronic component above the first dielectric layer, such that the second electronic component is coupled with the lateral portion of the first redistribution layer; and
forming a second dielectric layer above the first dielectric layer to cover the second electric component.

9. The method of claim 8, wherein the photo imageable dielectric material comprises one or more of photosensitive polyimide, polybenzoxazole (PBO), phenolic polymers, and benzocyclobutene polymers.

10. The method of claim 8, wherein the second dielectric layer comprises molding compound.

11. The method of claim 8, wherein forming the first redistribution layer in the first dielectric layer comprises:
attaching a dry film on the first dielectric layer;
performing photolithography and development processes on the dry film to form openings at locations where the first through hole is exposed and where the lateral portion of the first redistribution layer to be formed; and
filing the first through hole in the first dielectric layer and the openings in the dry film with conductive material to form the first redistribution layer.

12. The method of claim 11, wherein filing the openings in the dry film with conductive material comprises:
electroless-plating the conductive material on the first dielectric layer and the dry film, such that the conductive material fills the first through hole in the first dielectric layer and the openings in the dry film, and covers a top surface of the dry film; and
stripping the dry film and the conductive material formed thereon from the first dielectric layer, such that the conductive material left on the first dielectric layer forms the first redistribution layer.

13. The method of claim 8, wherein, before mounting the second electronic component above the first dielectric layer, the method further comprises:
forming a third dielectric layer on the first dielectric layer; and
forming a second redistribution layer in the third dielectric layer, wherein the second redistribution layer comprises a second vertical portion running through the third dielectric layer and coupled with the first lateral portion of the first redistribution layer, and a second lateral portion formed on a top surface of the third dielectric layer and coupled with the second electronic component.

14. The method of claim 13, wherein the third dielectric layer is made of photo imageable dielectric material, and forming the second redistribution layer in the third dielectric layer comprises:
performing photolithography and development processes on the third dielectric layer to form a second through hole in the third dielectric layer, wherein the second through hole exposes the first lateral portion of the first redistribution layer; and
electroless-plating conductive material on the third dielectric layer, such that the conductive material fills the second through hole in the third dielectric layer to form the second vertical portion of the second redistribution layer.

15. The method of claim 13, wherein, before forming the third dielectric layer on the first dielectric layer, the method further comprises:
mounting a third electronic component on the lateral portion of the first redistribution layer.

16. The method of claim 13, further comprising:
forming an electromagnetic interference (EMI) shielding layer over the second dielectric layer.
